(19) United States
(12) Patent Application Publication
(10) Pub. No.: US 2025/0068802 A1
(43) Pub. Date: Feb. 27, 2025

(54) NETWORK FOR BEHAVIOR MODELING

(71) Applicant: Micron Technology, Inc., Boise, ID (US)

(72) Inventors: Poorna Kale, Folsom, CA (US); Shashank Bangalore Lakshman, Folsom, CA (US); Pavana Prakash, Houston, TX (US); Febin Sunny, Folsom, CA (US)

(21) Appl. No.: 18/787,773

(22) Filed: Jul. 29, 2024

Related U.S. Application Data
(60) Provisional application No. 63/578,897, filed on Aug. 25, 2023.

(51) Int. Cl. G06F 30/27; G06F 30/15

(52) U.S. Cl. CPC G06F 30/27; G06F 30/15

(57) ABSTRACT

Systems, methods, and apparatuses related to a network for behavior modeling are described. A network can include surveillance devices that are each configured to collect pedestrian behavior data corresponding to a geographic region and output local pedestrian behavior model updates to a municipal communication node for the geographic region. The municipal communication node is configured to receive the local pedestrian behavior model updates and output the local pedestrian behavior model updates to a global pedestrian behavior model to aggregate the local pedestrian behavior model updates. A processing device is coupled to the municipal communication node and is configured to output the global pedestrian behavior model to the municipal communication node. The municipal communication node is configured to output the global pedestrian behavior model to an automatic driver assistance system (ADAS) in a vehicle within the geographic region, wherein the vehicle operates based on the global pedestrian behavior model.

### PRIORITY INFORMATION

This Application claims the benefit of U.S. Provisional Application No. 63/578,897, filed Aug. 25, 2023, the contents of which are included herein by reference.

### TECHNICAL FIELD

Embodiments of the disclosure relate generally to a network, and more specifically, relate to a network for behavior modeling.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), ferroelectric random access memory (FERAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

### BRIEF DESCRIPTION OF THE DRAWINGS

FIG. 1 illustrates an example computing system that includes a memory sub-system in accordance with some embodiments of the present disclosure.

FIG. 2 illustrates a network for behavior modeling in accordance with some embodiments of the present disclosure.

FIG. 3 illustrates an example of a system including a computing system in a vehicle in accordance with some embodiments of the present disclosure.

FIG. 4 illustrates an example of an automobile driver assistance system (ADAS) in a vehicle in accordance with some embodiments of the present disclosure.

FIG. 5 is a flow diagram illustrating a method for using a network for modeling behavior in accordance with some embodiments of the present disclosure.

FIG. 6 is a block diagram of an example computer system in which embodiments of the present disclosure may operate.

### DETAILED DESCRIPTION

The present disclosure includes apparatuses, methods, and systems for a network for behavior modeling. An embodiment includes a network that comprises a plurality of surveillance devices and a processing device (e.g., a component of a central server). Each of the surveillance devices can be configured to collect pedestrian behavior data, prepare a local pedestrian behavior model update based on the pedestrian behavior data, and transmit the local pedestrian behavior model update to a municipal communication node. The processing device can be coupled to the municipal communication node and configured to aggregate local pedestrian behavior model updates received from the plurality of surveillance devices in a global pedestrian behavior model and transmit the global pedestrian behavior model to a vehicle via the municipal communication node.

Autonomous vehicles operate in pedestrian-rich environments. Autonomous vehicles use a combination of multiple sensors and software to see and react to the pedestrians in the vicinity of the vehicles. As autonomous vehicles become more popular, recognizing pedestrian behavior for the safety of the pedestrians and the safety of occupants of the autonomous vehicles, becomes more important. Recognizing pedestrian behavior can involve large amounts of data and complex neural network models that use large amounts of memory and computation capabilities to train the neural network model (e.g. neural network). As used herein, the term “neural network” refers to a network that includes interconnected nodes in a layered structure that mimics the human brain to teach computers to process data in a way that is inspired by the human brain.

In previous approaches, manufacturers would train and deploy behavior models individually. Training and deploying behavior models individually involves collecting pedestrian behavior data and can result in encroaching on the privacy of the public, as well as consuming large amounts of resources (e.g., fuel, time, human effort, and cost) to collect the data and train the behavior model. Further, the difficulty in collecting the pedestrian behavior data can cause mistakes in the data collection that can result in errors in the data collection and errors during the training of the behavior model. Developing a generalized model for pedestrian behavior is a challenging task given the wide variety of behaviors and how these behaviors can vary from area to area (e.g., from city to city or even to various areas within the same city).

Embodiments of the present disclosure, however, can decrease the number of errors and the amount of resources used by the neural network model to collect the pedestrian behavior data and train the neural network model by implementing a federated learning system. As used herein, the term “federated learning system” refers to a method of training artificial intelligence (AI) models across multiple decentralized memory devices or servers holding local data samples without exchanging the data samples. Implementing a federated learning system into the neural network allows the neural network to utilize smart surveillance devices (e.g., smart cameras, traffic cameras, drones, etc.) within a geographic region (e.g., within or including areas of a town, a city, etc.) to train a global pedestrian behavior model for the geographic region. Each of the surveillance devices can collect local pedestrian behavior data, prepare an update to a local pedestrian behavior model (e.g., train the local model) on each respective surveillance device, and transmit updates of the local pedestrian behavior model to a municipal communication node to aggregate the updates received from the surveillance devices.

As used herein, the term “pedestrian behavior data” refers to data that describes the patterns of movement of people. In some embodiments, the pedestrian behavior data can be input into a plurality of pedestrian behavior models to update the pedestrian behavior models with the most recent pedestrian behavior data. These updates can be input into the global pedestrian behavior model to update the global pedestrian behavior model with the most current local pedestrian behavior models and to train the global pedestrian behavior model. Training the global pedestrian behavior model refers to the process of teaching the global pedestrian to perform a task. The global pedestrian behavior model can be trained by processing several data sets input into the global pedestrian behavior model and using those data sets as examples to allow the global pedestrian behavior model to process unknown inputs more accurately. For example, inputting the local pedestrian behavior model updates into the global pedestrian behavior model can train the global pedestrian behavior model because the global pedestrian behavior model can find patterns in the local pedestrian behavior data and apply those patterns to subsequent local pedestrian behavior models input into the global pedestrian behavior model. The municipal communication node can then output the global pedestrian behavior model to an ADAS of a vehicle.

Implementing the federated learning system allows for the collection of pedestrian behavior data using less resources than previous approaches because the collection is distributed across multiple devices, which may already be in the field. Furthermore, the central server aggregates updates to the pedestrian behavior model prepared by the individual surveillance devices instead of having to receive the pedestrian behavior data from the devices, which would require significant bandwidth, and perform a more resource intensive update based on that large amount of data. Implementing the federated learning system also decreases the instances of encroaching on the privacy of the public since the local pedestrian behavior data is not shared between different surveillance devices or between an individual surveillance device and a central server.

As used herein, “a,” “an,” or “a number of” can refer to one or more of something, and “a plurality of” can refer to two or more such things. For example, a memory device can refer to one or more memory devices, and a plurality of memory devices can refer to two or more memory devices. Additionally, the designator “N,” as used herein, particularly with respect to reference numerals in the drawings, indicates that a number of the particular feature so designated can be included with a number of embodiments of the present disclosure.

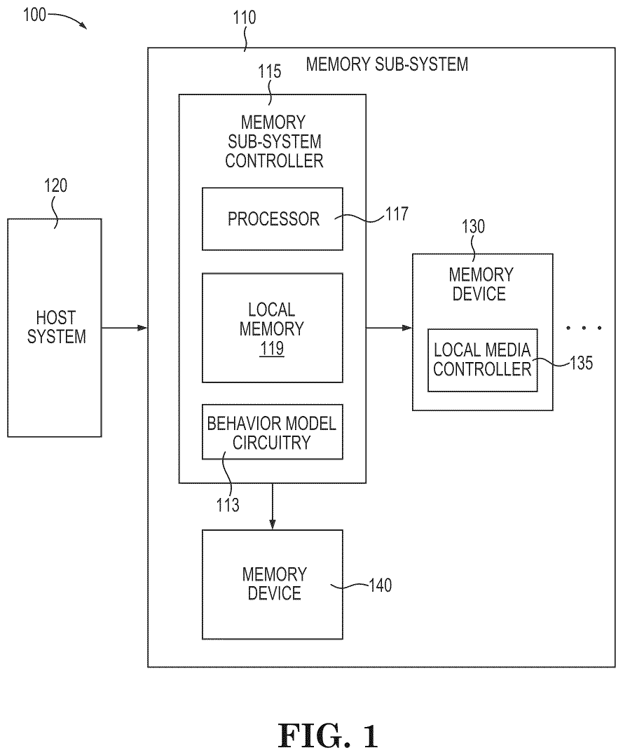

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 can be coupled to different types of memory sub-systems 110. FIG. 1 illustrates one example of a host system 120 coupled to one memory sub-system 110. As used herein, the term “coupled to” or “coupled with” can refer to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via an interface (e.g., a physical host interface). Examples of an interface can include, but are not limited to, a serial advanced technology attachment (SATA) interface, a peripheral component interconnect express (PCIe) interface, universal serial bus (USB) interface, Fibre Channel, Small Computer System Interface (SCSI), Serial Attached SCSI (SAS), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), Universal Serial Bus (USB), or any other interface. The interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The interface can provide a way for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as NAND type memory (e.g., 2D NAND, 3D NAND) are described, the memory device 130 can be based on any other type of non-volatile memory or storage device, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g. processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface (not pictured) circuitry to communicate with the host system 120 via a physical host interface (not pictured). The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

In some embodiments, the memory sub-system controller 115 can include behavior model circuitry (e.g., pedestrian behavior model circuitry) 113. The memory sub-system controller 115 can use the behavior model circuitry 113 to operate a vehicle based on a pedestrian behavior model stored in a memory device 130, 140. The memory sub-system 115 can further use the behavior model circuitry 113 to cause the pedestrian behavior model to be updated or replaced in the memory device 130, 140 in response to the vehicle entering a geographic region and/or a transceiver receiving an updated or new pedestrian behavior model that corresponds to the geographic region from the network of municipal communication nodes.

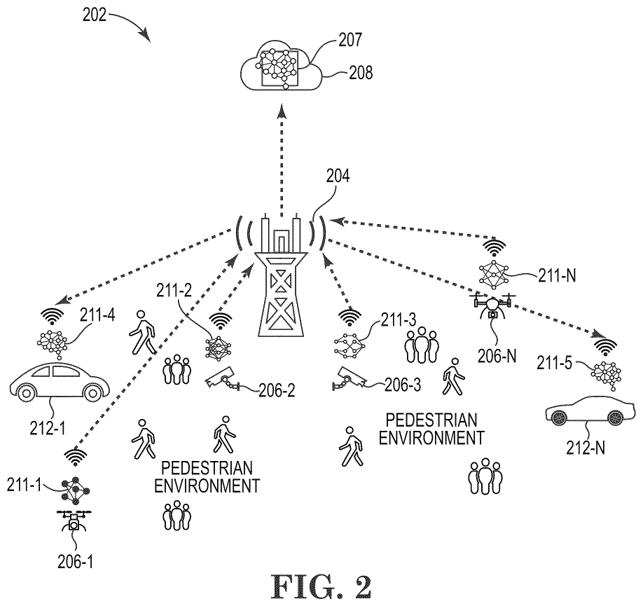

FIG. 2 illustrates a network for behavior modeling in accordance with some embodiments of the present disclosure. FIG. 2 includes a network 202 that comprises a municipal communication node 204, surveillance devices 206-1, 206-2, 206-3, . . . , 206-N (individually or collectively referred to as surveillance devices 206), a geographic pedestrian behavior model (not pictured), global pedestrian behavior model 207, local pedestrian behavior models 211-1, 211-2, 211-3, 211-4, 211-5, . . . , 211-N (individually or collectively referred to as local pedestrian behavior models 211), and autonomous vehicles 212-1, . . . , 212-N (individually or collectively referred to as autonomous vehicles 212).

The network 202 can cover all or a portion of an area covered by one cell phone tower or some other geographic region. A “geographic region” can include the area covered by one cell phone tower, multiple cell phone towers, or any specified area within and including a city, town, village, etc. The network 202 can include a plurality of surveillance devices 206. As used herein, the term “surveillance device” refers to a device that can be used to observe pedestrian behavior. Some embodiments include more than one type of surveillance device 206. For example, surveillance devices 206 can include drones (e.g., surveillance devices 206-1 and 206-N), cameras (e.g., surveillance devices 206-2 and 206-3), cell phones, or any other device that is capable of monitoring pedestrian behavior. The surveillance devices 206 can be configured to collect pedestrian behavior data. As stated above, the term “pedestrian behavior data” refers to data that describes the patterns of movement of people.

Each of the plurality of surveillance devices 206 can be configured to prepare an update to a local pedestrian behavior model 211 based on the pedestrian behavior data. As used herein, the term “local pedestrian behavior model” refers to the pedestrian behavior model 211 within a surveillance device 206. The local pedestrian behavior model 211 can be updated with the most recently available pedestrian behavior data gathered by a surveillance device 206. Each of the plurality surveillance devices 206 can be further configured to transmit the local pedestrian behavior model update to a municipal communication node 204. As used herein, the term “municipal communication node” refers to a communication tower that receives and transmits data within a geographic region. For example, the municipal communication node 204 can receive local behavior model updates from the plurality of surveillance devices 206 and transmit a global pedestrian behavior model 207 to an ADAS of the vehicles 212. In some embodiments, the ADAS of the vehicles 212 can include local pedestrian behavior models 211. In some embodiments, the municipal communication node 204 can be a 5G tower.

The network 202 can include a processing device 208 coupled to the municipal communication node 204. The processing device 208 can be physically coupled to the municipal communication node 204 or wirelessly coupled to the municipal communication node 204. In some embodiments, the processing device 208 can be in a separate location than the municipal communication node 204. In some embodiments, the processing device 208 can be a component of a central server configured to aggregate local pedestrian behavior model updates received from the plurality of surveillance devices 206 in the geographic region. The processing device 208 can receive the local pedestrian behavior model updates via the municipal communication node 204. The geographic pedestrian behavior model can be comprised of the aggregation of the updates to the local pedestrian behavior models 211 within a geographic region.

In some embodiments, the processing device 208 can be configured to maintain a plurality of geographic pedestrian behavior models. Each of the geographic pedestrian behavior models can be associated with a different geographic region. In some embodiments, the processing device 208 can aggregate the geographic pedestrian behavior models to form a global pedestrian behavior model 207 for a municipality (e.g., town, city, etc.). The processing device 208 can aggregate a particular local pedestrian behavior model update to a particular geographic pedestrian behavior model based on a location of a particular surveillance device 206 from which the local pedestrian behavior model update was received being within a geographic region associated with the particular geographic pedestrian behavior model.

In some embodiments, the network 202 can include a plurality of municipal communication nodes 204, wherein at least one of the plurality of municipal communication nodes 202 is configured to serve each of the different geographic regions. For example, the network 202 can include a first additional processing device 208 configured to aggregate a first additional local pedestrian behavior model updates to a first additional geographic pedestrian behavior model. The first additional local pedestrian behavior model 211 can be aggregated to the first additional geographic pedestrian behavior model based on a location of a first subset of the plurality of surveillance devices 206, from which the first additional local pedestrian behavior model updates were received, being within a first geographic region associated with the first additional geographic pedestrian behavior model. Further, a second additional processing device 208 can be configured to aggregate second additional local pedestrian behavior model updates to a second additional geographic pedestrian behavior model. The second additional local pedestrian model 211 can be aggregated to the second additional geographic pedestrian behavior model 211 based on a location of a second subset of the plurality of surveillance devices 206, from which the second additional local pedestrian behavior model updates were received, being within a second geographic region associated with the second additional geographic pedestrian behavior model.

In some embodiments, the plurality of surveillance devices 206 can be configured to collect first pedestrian behavior data in a first geographic region and prepare an update to a first local pedestrian behavior model 211 based on the first pedestrian behavior data. The plurality of surveillance devices 206 can be further configured to collect second pedestrian behavior data in a second geographic region and prepare an update to a second local pedestrian behavior model 211 based on the second pedestrian behavior data.

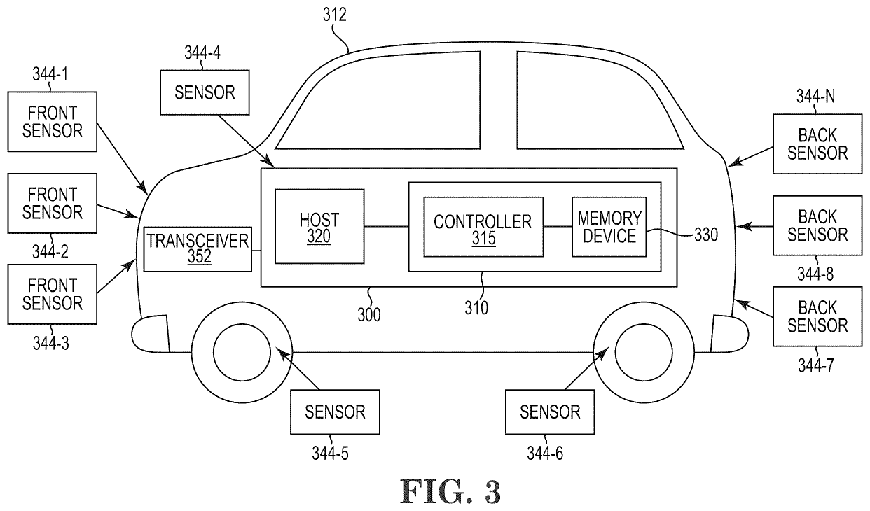

In some embodiments, a vehicle 212 can be configured to operate according to the most recently received global pedestrian behavior model 207. Further, a vehicle 212 can be configured to operate according to the global pedestrian behavior model 207 received from a nearest municipal communication node 204. In some embodiments, every municipal communication node 204 within the same network of municipal communication nodes 204 can have access to the same global pedestrian behavior model 207. Therefore, every municipal communication node 204 that contributes to a global pedestrian behavior model 207 has access to the same global pedestrian behavior model 207 and can transmit that same global pedestrian behavior model 207 to vehicles 212 within the range of a respective municipal communication node 204. Further, the vehicle 212 can be configured to operate according to a number of pedestrians in the vicinity of the vehicle 212. As used, herein, the term “vicinity” refers to a distance in which the sensors (e.g., sensors 344 in FIG. 3) can detect pedestrians.

In some embodiments, the pedestrian behavior in each of the plurality of geographic regions can be different. Further, the pedestrian behavior in different areas within a geographic region can be different. For example, pedestrian behavior in a suburban area of a geographic region may differ from pedestrian behavior in a downtown area of that same geographic region.

FIG. 3 illustrates an example of a system including a computing system 300 in a vehicle 312 in accordance with some embodiments of the present disclosure. The computing system 300 can include a memory sub-system 310, which is illustrated as including a controller 315 and non-volatile memory device 330 for simplicity, but is generally analogous to the memory sub-system 110 illustrated in FIG. 1. The computing system 300, and thus the host 320, can be coupled to a number of sensors 344 either directly, as illustrated for the sensor 344-4 or via a transceiver 352 as illustrated for the sensors 344-1, 344-2, 344-3, 344-5, 344-6, 344-7, 344-8, . . . , 344-N. The transceiver 352 is able to receive time based telemetric sensor data from the sensors 344 wirelessly, such as by radio frequency communication. In at least one embodiment, each of the sensors 344 can communicate with the computing system 300 wirelessly via the transceiver 352. In at least one embodiment, each of the sensors 344 is connected directly to the computing system 300 (e.g., via wires or optical cables). As used herein, the term “telemetric sensor data” refers to data that is collected by sensors 344 that are remote from the memory sub-system 310 that stores the data (the receiving equipment). The telemetric sensor data can include audio and visual data created by observing pedestrians using the sensors 344. In some embodiments, the telemetric sensor data can be applied to the pedestrian behavior model stored in the memory device 330 to operate the vehicle 312.

Each of the vehicles 312 can include an advanced driver assistance system (ADAS). As used herein, the term “ADAS” refers to a system to operate a vehicle based on a pedestrian behavior model stored in the ADAS. In some embodiments, an ADAS can include a memory device 330, a transceiver 352 configured to communicate with a network of municipal communication nodes (e.g., municipal communication nodes 204 in FIG. 2) and a controller 315 coupled to the memory device 330. The controller 315 can be configured to operate a vehicle 312 based on a pedestrian behavior model (e.g., global pedestrian behavior model 207 in FIG. 2 or a geographic pedestrian behavior model) stored in the memory device 330. The controller 315 can further be configured to cause the pedestrian behavior model to be updated or replaced in the memory device 330 in response to the vehicle 312 entering a geographic region and the transceiver 352 receiving an updated or new pedestrian behavior model that corresponds to the geographic region from the network of the municipal communication nodes.

The vehicle 312 can be a car (e.g., sedan, van, truck, etc.), a connected vehicle (e.g., a vehicle that has a computing capability to communicate with an external server), an autonomous vehicle (e.g., a vehicle with self-automation capabilities such as self-driving), a drone, a plane, a ship, and/or anything used for transporting people and/or goods. The sensors 344 illustrated in FIG. 3 can include example attributes. For example, sensors 344-1, 344-2, and 344-3 can be camera sensors collecting data from the front of the vehicle 312. Sensors 344-4, 344-5, and 344-6 can be microphone sensors collecting data from the from the front, middle, and back of the vehicle 312. The sensors 344-7, 344-8, and 344-N can be camera sensors collecting data from the back of the vehicle 312. As another example, the sensors 344-5 and 344-6 can be tire pressure sensors. As another example, the sensor 344-4 can be a navigation sensor, such as a global positioning system (GPS) receiver. As another example, the sensor 344-6 can be a speedometer. As another example, the sensor 344-4 can represent a number of engine sensors such as a temperature sensor, a pressure sensor, a voltmeter, an ammeter, a tachometer, a fuel gauge, etc. As another example, the sensor 344-4 can represent a video camera.

The ADAS can also include a host 320 coupled to the memory sub-system 310. The host 320 can execute instructions to provide an overall control system and/or operating system for the vehicle 312. In some embodiments, the host 320 can be a controller designed to assist in automation endeavors of the vehicle 312. For example, the host 320 can be an ADAS controller. An ADAS can monitor data to prevent accidents and provide warning of potentially unsafe situations. For example, the ADAS can monitor sensors 344 in the vehicle 312 and take control of vehicle 312 operations to avoid accident or injury (e.g., to avoid accidents in the case of an incapacitated user of a vehicle). The host 320 may need to act and make decisions quickly to avoid accidents. The memory sub-system 310 can store reference data in the non-volatile memory device 330 such that time based telemetric sensor data from the sensors 344 can be compared to the reference data by the host 320 in order to make quick decisions.

In some embodiments, the host 320 can be configured to determine a hierarchy of vehicle actions based on the pedestrian behavior model stored in the memory device 330. More specifically, a host 320 can determine the order in which it will instruct the vehicle 312 to perform an action when the conditions are met to execute multiple, different actions. For example, if the host 320, based on the pedestrian behavior model stored in the memory 330 and the pedestrian behavior being observed by sensors 344, determines that current conditions dictate that the vehicle 312 either brake or turn, the host 320 can prioritize either breaking or turning such that the prioritized action will occur first. In some embodiments, the action that was not prioritized may not occur. In some embodiments, the host 320 can be configured to operate the vehicle 312 with a previous version of the pedestrian behavior model in response to returning to a previous geographic region.

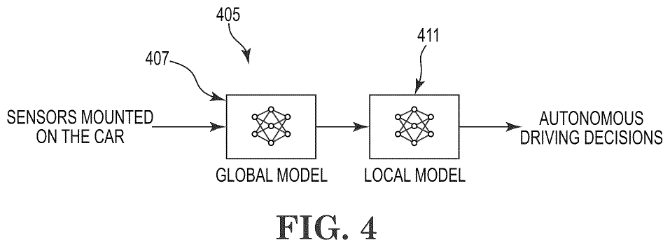

FIG. 4 illustrates an example of an automobile driver assistance system (ADAS) 405 in a vehicle in accordance with some embodiments of the present disclosure. As shown in FIG. 4, the ADAS 405 can include a global pedestrian behavior model 407 and a local pedestrian behavior model 411.

In some embodiments, sensors (e.g., sensors 344 in FIG. 3) mounted on the vehicle (e.g., vehicle 312 in FIG. 3) can collect data and send that data to the global pedestrian behavior model 407. The sensors can include cameras, light detection and ranging (LIDAR) sensors, radio detection and ranging (RADAR) sensors, etc. In some embodiments, the global pedestrian behavior model 407 can be stored on the ADAS 405 of the vehicle. In some examples, the global behavior model 407 can always be present in the ADAS 405 of the vehicle.

In some embodiments, the local pedestrian behavior model 411 can be acquired by a telematics component in the ADAS 405 based on global positioning system (GPS) coordinates. As used herein, the term “telematics” refers to communication services and applications that communicate with one another via GPS receivers and other telematics devices. The municipal communication node (e.g., municipal communication node 204 in FIG. 2) can include telematics components to send the local pedestrian behavior model 411 to the ADAS 405 of the vehicle. Unlike the global pedestrian behavior model 407, the same local pedestrian behavior model 411 may not be constantly stored on the ADAS 405. The local pedestrian behavior model 411 that is present in the ADAS 405 at a given time may be the local pedestrian behavior model 411 most recently received from a municipal communication node.

The global pedestrian behavior model 407 can send the information in the global pedestrian behavior model 407 to the local pedestrian behavior model 411 to integrate the information of the global behavior model 407 into the driving instructions for the vehicle. For example, the global behavior model 407 can use data (e.g., the path of roads sensed by the sensors, the movements of pedestrians sensed by the sensors, the status of traffic lights sensed by the sensors, etc.) collected by sensors mounted on the vehicle and integrate that data into the local pedestrian behavior model 411 to provide an environment in which the rules of the local pedestrian behavior model 411 will be applied. In other words, the global pedestrian behavior model 407 can provide data about the geographic region and the local pedestrian behavior model 411 can apply the local pedestrian behavior model updates received from the municipal communication node to the data about the geographic region to provide instructions to the vehicle on how to navigate the geographic region.

In some embodiments, the local pedestrian behavior model can include rules unique to the geographical region that includes the municipal communication node that sent the most recent update to the local pedestrian behavior model 411. For example, the rules of the local pedestrian behavior model 411 can change whether the geographical region is a downtown area or a suburban area. Further, the rules can change to accommodate the specific traffic laws of an area. For example, the local pedestrian behavior model 411 can include rules that incorporate local left-turn laws (e.g., left-turn on red allowed/disallowed for one-way to one-way turns), local right-turn laws (e.g., right-turn on red allowed/disallowed), and other local laws (e.g., stop sign as yield) that are unique to a specific geographic region or a specific group of geographic regions.

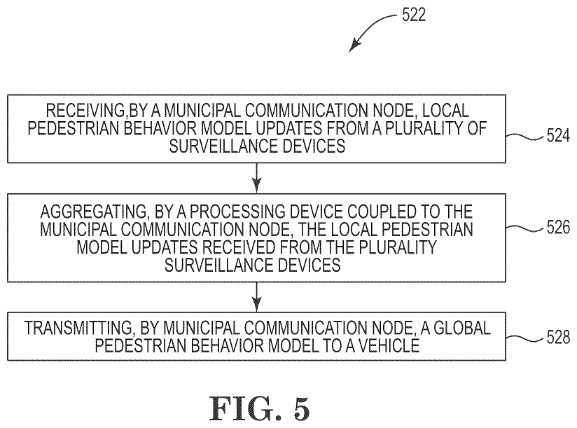

FIG. 5 is a flow diagram illustrating a method 522 for modeling behavior in accordance with some embodiments of the present disclosure. The method 522 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. As an example, the method 522 can be performed by the processing device 208 previously described in connection with FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 524, the method 522 can include receiving, by a municipal communication node (e.g., municipal communication node 204 in FIG. 2), local pedestrian behavior model updates from a plurality of surveillance devices (e.g., surveillance devices 206 in FIG. 2). The municipal communication node 204 can receive a first local pedestrian behavior model update from a first surveillance device 206-1 and receive a second local pedestrian behavior model update from a second surveillance device 206-2. In some embodiments, the first local pedestrian behavior model update can be different than the second local pedestrian behavior model update. Further, in some embodiments, the municipal communication node 204 can select a frequency at which the municipal communication node 204 receives the local pedestrian behavior model updates. For example, the municipal communication node 204 can select the amount of time that can pass between receiving first local pedestrian behavior model updates and the amount of time that can pass between receiving second local pedestrian behavior model updates. The municipal communication node 204 can further decide an amount of time that can pass between receiving a first local pedestrian model update and a second local pedestrian model update, as well as the amount of time that can pass between receiving a second local pedestrian model update and a first local pedestrian model update.

The municipal communication node 204 can send data to a central server (e.g., processing device 208 in FIG. 2). The data can be sent from the surveillance devices 206 to the municipal communication node 204 and the municipal communication node 204 can send the received data to the processing device 208. In this context, “data” refers to models or model updates rather than to pedestrian behavior data. In some embodiments, every municipal communication node 204 within a network 202 of municipal communication nodes 204 can send the data to the same processing device 208. Before sending the data to the processing device 208, the municipal communication nodes 204 can aggregate the received data into a geographic pedestrian behavior model based on the pedestrian behavior data collected by surveillance devices 206 associated with each respective municipal communication node 204.

At block 526, the method 522 can include aggregating, by a processing device 208 coupled to the municipal communication node 204, the local pedestrian model updates received from the plurality of surveillance devices 206. The processing device 208 can aggregate the local pedestrian behavior models 211 received from the municipal communication nodes 204 associated with the central server 208 into a global pedestrian behavior model 207, 407. The global pedestrian behavior model 207, 407 can be a model of the behavior of pedestrians within the geographic area corresponding to the entire network 202 of the municipal communication nodes 204.

The processing device 208 can send the global pedestrian behavior model 207, 407 to at least one of the municipal communication nodes 204 within the network 202 of municipal communication nodes 204. In some embodiments, the central server 208 can send the global pedestrian behavior model 207, 407 to every municipal communication node 204 in the network 202 of municipal communication nodes 204 simultaneously.

At block 528, the method 522 can include transmitting, by the municipal communication node 204, a global pedestrian behavior model 207, 407 to a vehicle 212, 312. In some embodiments, the municipal communication node 204 can select a frequency at which the municipal communication node 204 transmits the local pedestrian behavior model 211 to the vehicle 212, 312. For example, the municipal communication node 204 can select an amount of time that passes between the instances of the municipal communication node 204 sending the global pedestrian behavior model 207, 407 to the vehicle 212, 312.

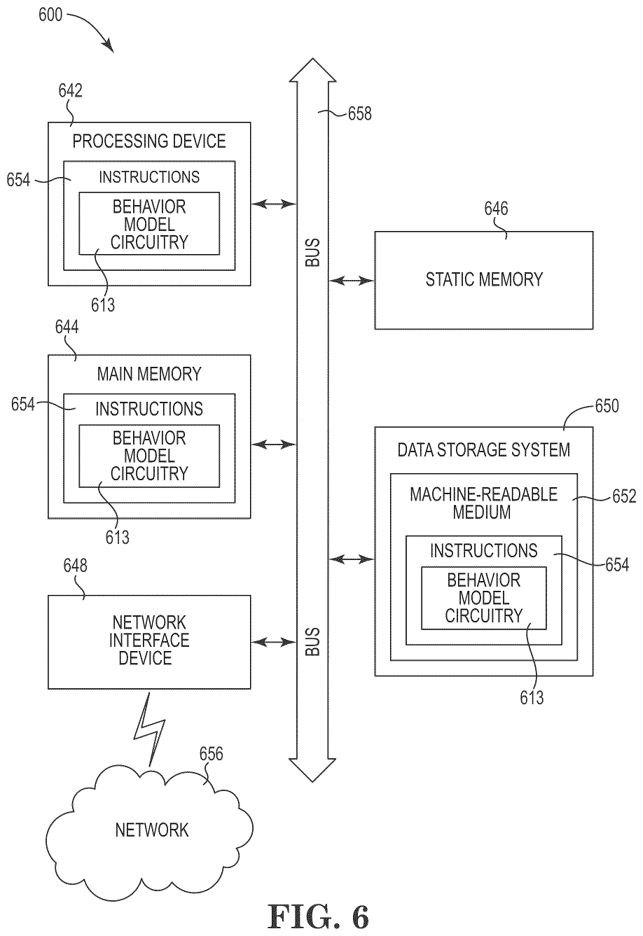

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 in FIG. 1) that includes, is coupled to, or utilizes a memory sub-system (e.g., the memory sub-system 110 in FIG. 1) or can be used to perform the operations of a controller (e.g., to execute an operating system to perform operations corresponding to the behavior model circuitry 613). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 642, a main memory 644 (e.g., read-only memory (ROM), flash memory, dynamic random access memory (DRAM) such as synchronous DRAM (SDRAM) or Rambus DRAM (RDRAM), etc.), a static memory 646 (e.g., flash memory, static random access memory (SRAM), etc.), and a data storage system 650, which communicate with each other via a bus 658.

The processing device 642 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 642 can also be one or more special-purpose processing devices such as an application specific integrated circuit (ASIC), a field programmable gate array (FPGA), a digital signal processor (DSP), network processor, or the like. The processing device 642 is configured to execute instructions 654 for performing the operations and steps discussed herein. The computer system 600 can further include a network interface device 648 to communicate over the network 656.

The data storage system 650 can include a machine-readable storage medium 652 (also known as a computer-readable medium) on which is stored one or more sets of instructions 654 or software embodying any one or more of the methodologies or functions described herein. The instructions 654 can also reside, completely or at least partially, within the main memory 644 and/or within the processing device 642 during execution thereof by the computer system 600, the main memory 644 and the processing device 642 also constituting machine-readable storage media. The machine-readable storage medium 652, data storage system 650, and/or main memory 644 can correspond to the memory sub-system 110 in FIG. 1.

In one embodiment, the instructions 654 include instructions to implement functionality corresponding to behavior modeling (e.g., behavior modeling circuitry 113 in FIG. 1). While the machine-readable storage medium 652 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A network, comprising:
a plurality of surveillance devices, each configured to collect pedestrian behavior data corresponding to a geographic region and output local pedestrian behavior model updates to a municipal communication node for the geographic region;
the municipal communication node configured to receive the local pedestrian behavior model updates and output the local pedestrian behavior model updates to a global pedestrian behavior model to aggregate the local pedestrian behavior model updates;
a processing device coupled to the municipal communication node and configured to output the global pedestrian behavior model to the municipal communication node; and
the municipal communication node further configured to output the global pedestrian behavior model to an automatic driver assistance system (ADAS) in a vehicle within the geographic region, wherein the vehicle is configured to operate within the geographic region based on the global pedestrian behavior model.

2. The network of claim 1, wherein the processing device is configured to transmit the global pedestrian behavior model to any vehicle in response to the vehicle first coming into contact with the municipal communication node.

3. The network of claim 1, wherein the processing device is configured to:
maintain a plurality of geographic pedestrian behavior models, each associated with a different geographic region; and
aggregate a particular local pedestrian behavior model update to a particular geographic pedestrian behavior model based on a location of a particular surveillance device from which the local pedestrian behavior model update was received being within a geographic region associated with the particular geographic pedestrian behavior model.

4. The network of claim 3, further comprising a plurality of municipal communication nodes, at least one of the plurality of municipal communication nodes configured to serve each of the different geographic regions.

5. The network of claim 4, further comprising:
a first additional processing device configured to aggregate first additional local pedestrian behavior model updates to a first additional geographic pedestrian behavior model based on a location of a first subset of the plurality of surveillance devices from which the first additional local pedestrian behavior model updates were received being within a first geographic region associated with the first additional geographic pedestrian behavior model; and
a second additional processing device configured to aggregate second additional local pedestrian behavior model updates to a second additional geographic pedestrian behavior model based on a location of a second subset of the plurality of surveillance devices from which the second additional local pedestrian behavior model updates were received being within a second geographic region associated with the second additional geographic pedestrian behavior model.

6. The network of claim 4, wherein the plurality of surveillance devices are further configured to:
collect first pedestrian behavior data in a first geographic region;
prepare an update to a first local pedestrian behavior model based on the first pedestrian behavior data;
collect second pedestrian behavior data in a second geographic region; and
prepare an update to a second local pedestrian behavior model based on the second pedestrian behavior data.

7. The network of claim 4, wherein the vehicle is configured to operate according to a most recently received global pedestrian behavior model.

8. The network of claim 4, wherein the vehicle is configured to operate according to a number of pedestrians in a vicinity of the vehicle.

9. The network of claim 3, wherein the geographic region is a municipality.

10. The network of claim 3, wherein pedestrian behavior in each of the plurality of geographic regions is different.

11. The network of claim 1, wherein the municipal communication node is a 5G tower.

12. The network of claim 1, wherein the processing device is configured to train the global pedestrian behavior model before the global pedestrian behavior model is transmitted to the vehicle.

13. The network of claim 1, wherein a first surveillance device is a first type of surveillance device and a second surveillance device is a second type of surveillance device.

14. A method, comprising:
receiving, by a municipal communication node, local pedestrian behavior model updates from a plurality of surveillance devices;
aggregating, by a processing device coupled to the municipal communication node, the local pedestrian model updates received from the plurality surveillance devices; and
transmitting, by the municipal communication node, a global pedestrian behavior model to a vehicle.

15. The method of claim 14, wherein receiving local pedestrian behavior model updates comprises:
receiving a first local pedestrian behavior model update from a first surveillance device; and
receiving a second local pedestrian behavior model update from a second surveillance device; and
wherein the first local pedestrian behavior model update is a different than the second local pedestrian behavior model update.

16. The method of claim 14, further comprising selecting, by the municipal communication node, a frequency at which the municipal communication node receives the local pedestrian behavior model updates.

17. The method of claim 14, further comprising selecting, by the municipal communication node, a frequency at which the municipal communication node transmits the global pedestrian behavior model to the vehicle.

18. An advanced driver assistance system (ADAS), comprising:
a memory device;
a transceiver configured to communicate with a network of municipal communication nodes; and
a controller coupled to the memory device and to the transceiver, wherein the controller is configured to:
operate a vehicle based on a pedestrian behavior model stored in the memory device; and
cause the pedestrian behavior model to be updated or replaced in the memory device in response to:
the vehicle entering a geographic region; and
the transceiver receiving an updated or new pedestrian behavior model that corresponds to the geographic region from the network of municipal communication nodes.

19. The ADAS of claim 18, wherein the controller is configured to determine a hierarchy of vehicle actions based on the pedestrian behavior model stored in the memory.

20. The ADAS of claim 18, wherein the controller is configured to operate the vehicle with a previous version of the pedestrian behavior model in response to returning to a previous geographic region.
